(19) United States
(12) Patent Application Publication
(10) Pub. No.: US 2014/0345520 A1
(43) Pub. Date: Nov. 27, 2014

(54) PRINTED CIRCUIT BOARD FILM

(71) Applicants: HONG FU JIN PRECISION INDUSTRY (ShenZhen) CO., LTD., Shenzhen (CN); HON HAI PRECISION INDUSTRY CO., LTD., New Taipei (TW)

(72) Inventors: SZE-YU LIN, New Taipei (TW); HUI LUO, Shenzhen (CN)

(73) Assignees: HONG FU JIN PRECISION INDUSTRY (ShenZhen) CO., LTD., Shenzhen (CN); HON HAI PRECISION INDUSTRY CO., LTD., New Taipei (TW)

(21) Appl. No.: 14/288,353

(22) Filed: May 27, 2014

(30) Foreign Application Priority Data
May 27, 2013 (CN) 2013102007585

(51) Int. Cl. H05K 3/34

(52) U.S. Cl. CPC H05K 3/3452
USPC 118/505

(57) ABSTRACT

A film of a printed circuit board (PCB) (5) includes a top film (1) with a first solder mask spot (11) and a bottom film (2) with a second solder mask spot (21). When the top film (1) and the bottom film (2) are placed on a top layer and a bottom layer of the PCB (5) respectively, concentric circles are formed by the first solder mask spot (11), a hole (8) defined on the PCB (5), and the second solder mask spot (21). A diameter of the first solder mask spot (11), a diameter the second solder mask spot (21), and a diameter of the hole (5) represent a plugged depth of the hole (8).

### FIELD

The subject matter herein generally relates to films, in particularly to films for printed circuit boards (PCBs).

### BACKGROUND

Sometimes, holes on PCBs need to be plugged or partially plugged.

### BRIEF DESCRIPTION OF THE DRAWINGS

Implementations of the present technology will now be described, by way of example only, with reference to the attached figures, wherein:

FIG. 1 is a schematic diagram of an embodiment of a film.

FIG. 2 is cross-section diagram of a PCB corresponding to the film of FIG. 1.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. The drawings are not necessarily to scale and the proportions of certain parts may be exaggerated to better illustrate details and features. The description is not to be considered as limiting the scope of the embodiments described herein.

Several definitions that apply throughout this disclosure will now be presented.

The term “substantially” is defined to be essentially conforming to the particular dimension, shape or other word that substantially modifies, such that the component need not be exact. For example, substantially cylindrical means that the object resembles a cylinder, but can have one or more deviations from a true cylinder. The term “comprising” means “including, but not necessarily limited to”; it specifically indicates open-ended inclusion or membership in a so-described combination, group, series and the like.

The present disclosure is described in relation to a film of a printed circuit board (PCB) to represent a depth of plug holes in the PCB.

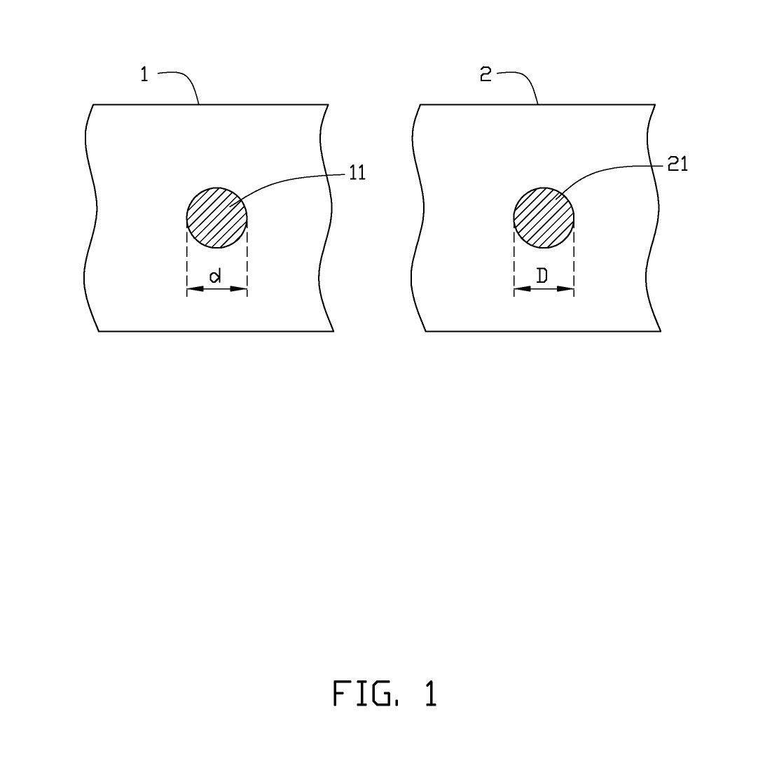

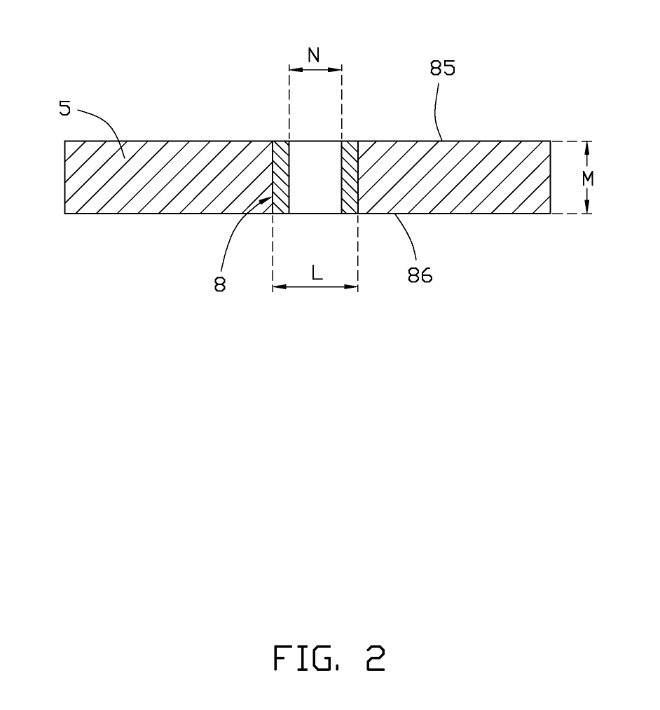

FIG. 1 illustrates an embodiment of the film of the PCB. The film of the PCB may comprise a top film 1 and a bottom film 2. The top film 1 can be placed on the top surface of a PCB 5 and the bottom film 2 can be placed on a bottom surface of the PCB 5 (see FIG. 2).

FIG. 2 illustrates that a hole 8 is defined in the PCB 5. An external diameter of the hole 8 is L, an internal diameter is N, and a depth of the hole 8 is M. The hole 8 is a conductor which can connect and conduct signal between a first conductive layer 85 of the PCB 5 and a second conductive layer 86 of the PCB 5. In the embodiment, the first conductive layer 85 and the second conductive layer 86 are non-adjacent layers of the PCB 5.

A solder mask spot 11 is located on the top film 1, and a diameter of the spot 11 is defined by distance d. A solder mask spot 21 is located on the bottom film 2, and a diameter of the spot 21 is defined by distance D. When the top film 1 and the bottom film 2 are placed on the top surface and the bottom surface of the PCB 5 respectively, concentric circles are formed by the solder mask spot 11, the hole 8, and the solder mask spot 21.

In the embodiment, a depth of the plugged hole 8 is represented by the diameter d of the spots 11 and the diameter D of the spot 12.

For example, when the diameters d and D are equal to the external diameter L of the hole 8, namely when d=D=L, the hole 8 is not needed to be plugged.

When the diameters d and D are equal to half of the internal diameter N of the hole 8, namely when d=D=N/2, the hole 8 is fully plugged.

When the diameter d of the spot 11 is equal to half of the internal diameter N of the hole 8, and the diameter D of the spot 21 is equal to the external diameter L of the hole 8, namely when D=L, and d=N/2, the hole 8 is plugged by the first conductive layer 85, the plugged depth of the hole 8 is half of the depth M of the hole 8.

When the diameter d of the spot 11 is equal to the external diameter L of the hole 8, and the diameter D of the spot 21 is equal to one-third of the internal diameter N of the hole 8, namely when D=N/3, d=L, the hole 8 is plugged by the second conductive layer 86, the plugged depth of the hole 8 is two-thirds of the depth M of the hole 8.

In the embodiment, the less of the diameter d of the spot 11 and the diameter D of the spot 21, the greater of the depth of the plug hole 8. In the other embodiment, relation between the diameters d and D and the depth of the plug hole 8 can be varied as needed.

The embodiments shown and described above are only examples. Even though numerous characteristics and advantages of the present technology have been set forth in the foregoing description, together with details of the structure and function of the present disclosure, the disclosure is illustrative only, and changes may be made in the detail, including in matters of shape, size and arrangement of the parts within the principles of the present disclosure up to, and including, the full extent established by the broad general meaning of the terms used in the claims.

What is claimed is:

1. A film of a printed circuit board (PCB) (5), comprising a top film (1) with a first solder mask spot (11) and a bottom film (2) with a second solder mask spot (21), wherein when the top film (1) and the bottom film (2) are placed on a top surface and a bottom surface of the PCB (5) respectively, concentric circles are formed by the first solder mask spot (11), and a hole (8) defined in the PCB and the second solder mask spot (21), a diameter of the first solder mask spot (11), a diameter of the second solder mask spot (21), and a diameter of the hole (8), represent a plugged depth of the hole (8).

2. The film of claim 1, wherein when the diameters of the first solder mask spot (11) and the second solder mask spot (21) are equal to an external diameter of the hole (8), the hole (8) is not plugged.

3. The film of claim 1, wherein when the diameters of the first solder mask spot (11) and the second solder mask spot (21) are equal to half of an internal diameter of the hole (8), the hole (8) is fully plugged.

4. The film of claim 1, wherein when the diameter of the first solder mask spot (11) is equal to half of an internal diameter of the hole (8), and the diameter of second solder mask spot (21) is equal to an external diameter of the hole (8), the hole (8) is plugged by a top conductive layer (85) and the plugged depth of the hole (8) is half of the depth of the hole (8).

5. The film of claim 1, wherein when the diameter of the first solder mask spot (11) is equal to an external diameter of the hole (8) and the diameter of second solder mask spot (21) is equal to one-third of an internal diameter of the hole (8), the hole (8) is plugged by a bottom conductive layer (86), and the plugged depth of the hole (8) is two-thirds of the depth of the hole (8).
